(19) United States
(12) Patent Application Publication
(10) Pub. No.: US 2024/0107892 A1
(43) Pub. Date: Mar. 28, 2024

(54) MAGNETORESISTANCE SENSOR WITH BIASED FREE LAYER FOR IMPROVED STABILITY OF MAGNETIC PERFORMANCE

(71) Applicant: Apple Inc., Cupertino, CA (US)

(72) Inventors: Jason Janesky, Campbell, CA (US); Jodi M. Iwata-Harms, San Carlos, CA (US); Savas Gider, San Jose, CA (US)

(21) Appl. No.: 17/934,969

(22) Filed: Sep. 23, 2022

(51) Int. Cl. H01L 43/08; G01R 33/09; G11C 11/16; H01F 10/32; H01L 43/10

(52) U.S. Cl. CPC H01L 43/08; G01R 33/093; G11C 11/161; H01F 10/3272; H01L 43/10

(57) ABSTRACT

The enclosed embodiments are directed to a magnetoresistance (MR) sensor with a biased free layer for improved stability of magnetic performance. In an embodiment, an MR sensor comprises: a first antiferromagnetic (AF) pinning layer; a magnetic fixed layer disposed on the first AF layer; a tunnel barrier disposed on the magnetic fixed layer; a magnetic coupled free layer disposed on the tunnel barrier; a AF coupling layer disposed on the magnetic coupled free layer; a magnetic pinned layer disposed on the AF coupling layer; and a second AF pinning layer disposed on the magnetic pinned layer. In an embodiment, a method of unpinning a pinned free layer uses a current pulse through the MR sensor to self-heat above a blocking temperature of the AF pinning layer, and then reading the MR sensor after the current pulse is reduced or removed and the MR sensor cools back below the blocking temperature.

### TECHNICAL FIELD

This disclosure relates generally to magnetoresistance (MR) sensors.

### BACKGROUND

A MR sensor measures a magnetic field based on the change of resistivity of a current carrying ferromagnetic material through the influence of a magnetic field, referred to as the MR effect. A giant MR (GMR) sensor utilizes the MR effect observed in multilayers composed of alternating ferromagnetic and non-magnetic conductive layers to measure changes in the magnetic field. A tunnel magnetoresistance (TMR) sensor utilizes the MR effect observed in multilayers comprising an extremely thin nanometer-level, non-magnetic insulation layer, disposed between two ferromagnetic layers.

FIG. 1 is a generalized view of a typical TMR sensor stack 100 comprising free magnetic layer 101 and fixed magnetic layer 103 separated by tunnel barrier 102. The magnetization direction of fixed magnetic layer 103 is pinned in a specific direction through operation or during sensor processing. The magnetization direction of free magnetic layer 101 is free to rotate from the influence of an external magnetic field. Limitations of TMR sensor stack 100 include: 1) the magnetic behavior of free magnetic layer 101 is primarily determined by its material composition and the shape of the sensor through shape anisotropy; 2) tight control of material thickness, composition and sensor shape are required to produce a desired magnetic performance such as full scale external field range; and 3) non-uniformities in the sensor shape, such as processing defects, can cause increased sensor noise.

### SUMMARY

Embodiments are disclosed for a MR sensor with a biased free layer for improved stability of magnetic performance.

In an embodiment, a magnetoresistance (MR) sensor comprises: a first antiferromagnetic (AF) pinning layer; a magnetic fixed layer disposed on the first AF layer; a tunnel barrier disposed on the magnetic fixed layer; a magnetic coupled free layer disposed on the tunnel barrier; a AF coupling layer disposed on the magnetic coupled free layer; a magnetic pinned layer disposed on the AF coupling layer; and a second AF pinning layer disposed on the magnetic pinned layer.

In an embodiment, a hard magnetization axis of the magnetic coupled free layer is orientated at about 90 degrees to a pinning direction of the magnetic pinned layer.

In an embodiment, a saturation field of the coupled free layer in a hard axis direction is defined by a coupling to the pinned layer through the AF coupling layer.

In an embodiment, a thickness of the AF coupling layer controls a saturation field of the coupled free layer in a hard axis direction.

In an embodiment, the AF coupling layer provides a bias direction based on a magnetization direction of the pinned layer to reset the MR sensor.

In an embodiment, the first AF pinning layer and the second AF pinning layer comprise different AF materials.

In an embodiment, the first AF pinning layer and the second AF pinning layer comprise different thicknesses.

In an embodiment, the second AF pinning layer is below the tunnel barrier and the first AF pinning layer is above the tunnel barrier.

In an embodiment, the first or second AF pinning layers are composed of at least one of platinum manganese (PtMn), iridium manganese (IrMn), rhodium manganese (RhMn) or iron manganese (FeMn).

In an embodiment, a MR sensor comprises: a first antiferromagnetic (AF) pinning layer; a magnetic fixed layer disposed on the first AF layer; a tunnel barrier disposed on the magnetic fixed layer; a magnetic pinned free layer disposed on the tunnel barrier; and a second AF pinning layer disposed on the pinned free layer.

In an embodiment, a hard axis curve (MR versus field) of the pinned free layer is substantially linear and has a direction of magnetization that saturates in the hard axis direction based on an exchange coupling in the second AF pinning layer.

In an embodiment, an exchange strength of the exchange coupling is determined by a thickness of the second AF pinning layer.

In an embodiment, an exchange strength of the exchange coupling is controlled by material deposition conditions (e.g., composition of the AF pinning, roughness) of the pinned free layer and AF pinning layer.

In an embodiment, the MR sensor further comprises a second barrier disposed on the magnetic pinned free layer.

In an embodiment, the second barrier reduces and controls the coupling of the pinned free layer to the second AF pinning layer.

In an embodiment, a thickness of the second barrier is less than 1 nanometer.

In an embodiment, the second AF pinning layer is below the tunnel barrier and the first AF pinning layer is above the tunnel barrier.

In an embodiment, the second barrier is composed of at least one of tungsten (W), tantalum (Ta), Ruthenium (Ru), aluminum (Al) or magnesium (Mg).

In an embodiment, a method of reading from a magnetoresistance (MR) sensor, comprises: passing an electrical current through the MR sensor, the MR sensor comprising a first antiferromagnetic (AF) pinning layer, a magnetic fixed layer disposed on the first AF layer, a tunnel barrier disposed on the magnetic fixed layer, a magnetic pinned free layer disposed on the tunnel barrier, and a second AF pinning layer disposed on the magnetic pinned layer, the current causing self-heating of the MR sensor that unpins the pinned free layer from the second AF pinning layer and allows it to freely rotate in an external field; removing or reducing the electrical current from the MR sensor, the removal of electrical current causing the pinned free layer to cool and re-pin to a new direction based on the external field or shape anisotropy; and reading from the MR sensor.

In an embodiment, the first and second AF pinning layers comprise different AF materials, and the method further comprises: setting the first AF pinning layer at a first anneal temperature in a first field direction; and setting the second AF pinning layer at a second anneal temperature in a second field direction that is different than the first field direction, where the second anneal temperature is lower than the first anneal temperature.

In an embodiment, saturation fields of magnetic material coupled to the first and second AF pinning layers are different, and the method further comprises: applying a first field having a first field strength to the MR sensor in a first direction of magnetization; and applying a second field having a second field strength that is lower than the first field strength to the MR sensor in a second direction of magnetization that is about 90 degrees from the first direction of magnetization, such that a magnetization direction of the fixed layer stays in the first direction of magnetization and the pinned layer rotates into the first direction of magnetization plus about 90 degrees.

Advantages of the disclosed embodiments include magnetic performance that relies on material properties, is uniform along the entire length of the sensor and is tunable without changes to the free layer thickness or composition.

The details of one or more implementations of the subject matter are set forth in the accompanying drawings and the description below. Other features, aspects and advantages of the subject matter will become apparent from the description, the drawings and the claims.

### BRIEF DESCRIPTION OF THE DRAWINGS

FIG. 1 illustrates a generalized view of a typical TMR sensor design

FIG. 2 illustrates a MR sensor stack with an added AF pinning layer and free layer composed of a synthetic AF stack using an AF coupling layer, according to an embodiment.

FIG. 3 illustrates the magnetization direction of the coupled free layer when an external magnetic field is applied about 90 degrees to the pinned layer, according to an embodiment.

FIG. 4 illustrates the magnetization direction of the coupled free layer when external magnetic field is applied along the pinned layer, according to an embodiment.

FIG. 5 illustrates hard axis response curves (MR vs field) using a macro-spin model for magnetization M (emu/cm³) with various values of the anisotropy K (erg/cm³) and coupling J (erg/cm²), according to an embodiment.

FIG. 6 illustrates field direction and anneal temperature versus time for setting the AF pinning layers shown in FIG. 2, according to an embodiment.

FIG. 7 illustrates field magnitude and direction and anneal temperature versus time for setting the AF pinning layers shown in FIG. 2, according to an embodiment.

FIG. 8 illustrates an alternative embodiment of a MR sensor stack with a free magnetic layer coupled to an AF pinning layer through a barrier layer, according to an embodiment.

FIGS. 9 and 10 illustrates an operation where electric current is passed through a MR sensor stack to unpin the pinned layer so that it freely rotates in an external field, and then removing the current to re-pin the layer in a new direction based on an external field, according to an embodiment.

FIG. 11 is a block diagram of an electronic device architecture that includes at least one magnetometer as described in reference to FIGS. 2-10, according to an embodiment.

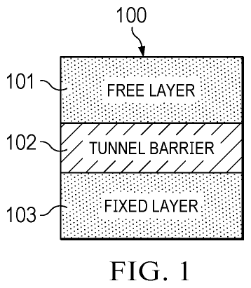

### DETAILED DESCRIPTION

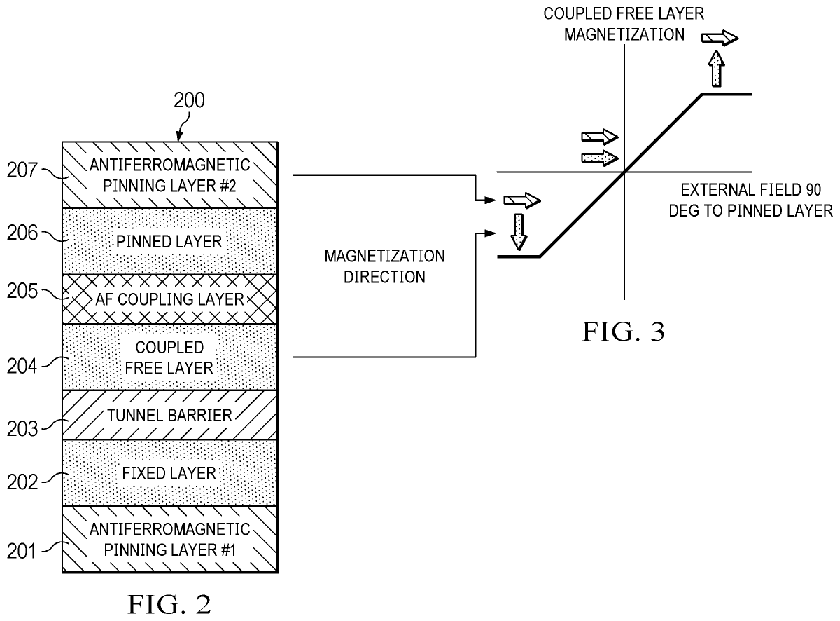

FIG. 2 illustrates a MR sensor stack 200 with an added AF pinning layer and a free layer composed of a synthetic AF stack utilizing an AF coupling layer, according to an embodiment. More particularly, MR sensor stack 200 includes first synthetic AF pinning layer 201 (also referred to as AF pinning layer #1), fixed layer 202, tunnel barrier 203, coupled free layer 204, AF coupling layer 205, pinned layer 206 and second synthetic AF pinning layer 207 (also referred to as AF pinning layer #2).

In this embodiment, AF pinning layers 201, 207 are made of AF materials, such as platinum manganese (PtMn), iridium manganese (IrMn), rhodium manganese (RhMn), iron manganese (FeMn) or any other suitable AF material. Coupled free layer 204 is composed of a synthetic AF stack using AF coupling layer 205 made of, for example, ruthenium (Ru), iridium (Ir) or rhodium (Rh).

Although FIG. 2 shows two magnetic layers 202, 204, three or more magnetic layers can be used in MR sensor stack 200 to mediate the coupling between coupled free layer 204 and pinned layer 206. In this example design, the hard axis of magnetization of coupled free layer 204 is defined as about 90 degrees to the pinning direction.

In an alternative embodiment, MR sensor stack 200 is a GMR sensor stack with metallic layers (e.g., Cu) between the ferromagnetic layers.

FIG. 3 illustrates the magnetization direction of coupled free layer 204 when an external magnetic field is applied about 90 degrees to pinned layer 206, according to an embodiment. The directions are indicated by the corresponding arrows in FIG. 3. The saturation field of coupled free magnetic layer 204 in the hard axis of magnetization direction is defined by the coupling to the pinned layer 206 through AF coupling layer 205. This is controlled by the thickness of AF coupling layer 205.

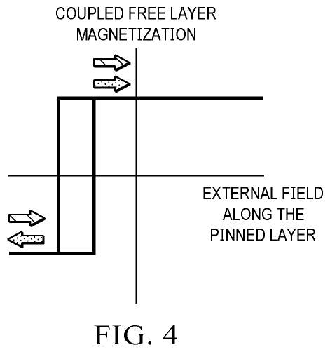

FIG. 4 illustrates the magnetization direction of the coupled free layer when an external magnetic field is applied along pinned layer 206, according to an embodiment. AF coupling layer 205 provides a bias direction based on the magnetization direction of pinned layer 206. The bias provides a stable reset to the entire length of MR sensor stack 200 by aligning the magnetic coupled free layer in a consistent remanent direction and helps reduce noise.

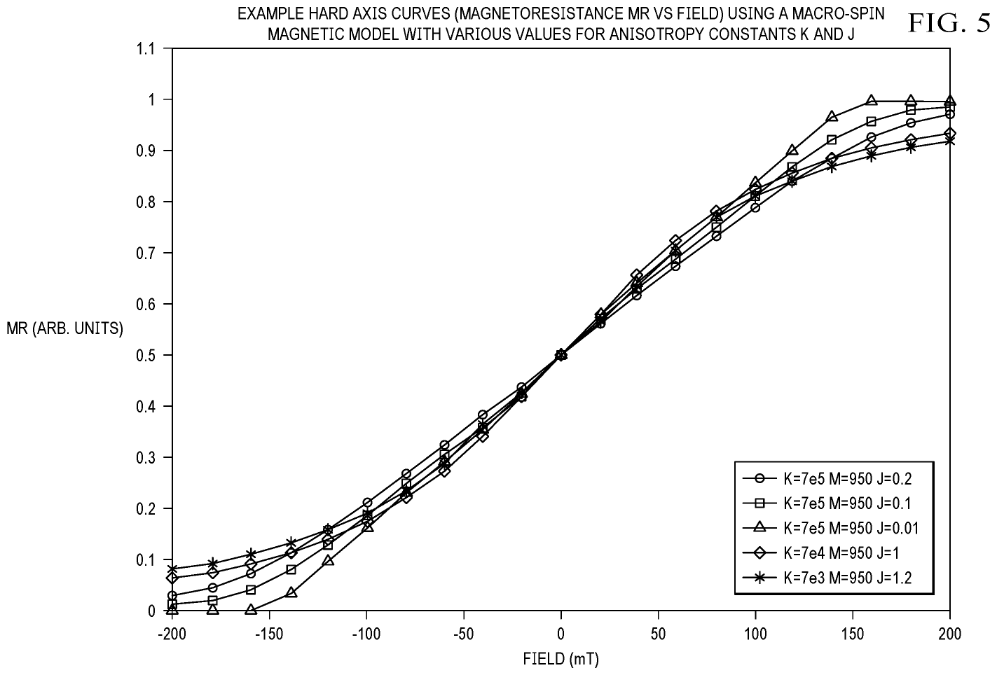

FIG. 5 illustrates hard axis response curves (MR vs field) using a macro-spin magnetic model with various values for anisotropy constants K and J, according to an embodiment. The response curves can be estimated by minimizing the total magnetostatic energy. The total magneto static energy versus angle for a pinned free layer can be approximated by Equation [1]:

E(t)=K sin²(t)−HM cos(a−t)−JA cos(t) [1]
E=total magnetostatic energy density
K=anisotropy energy (erg/cm³)
H=applied field (mT)
M=magnetization (emu/cm³)
J=exchange coupling of the AF pinning layer (erg/cm²)
A=coupling area
a=the angle between the applied field and the magnetization
T=the angle between the exchange axis and the magnetization.

Equation [1] is for the case where the exchange bias and shape anisotropy are along the same axis, as in the embodiment shown in FIG. 2. Minimizing E(t) with respect to t provides the stable magnetization angle versus applied field.

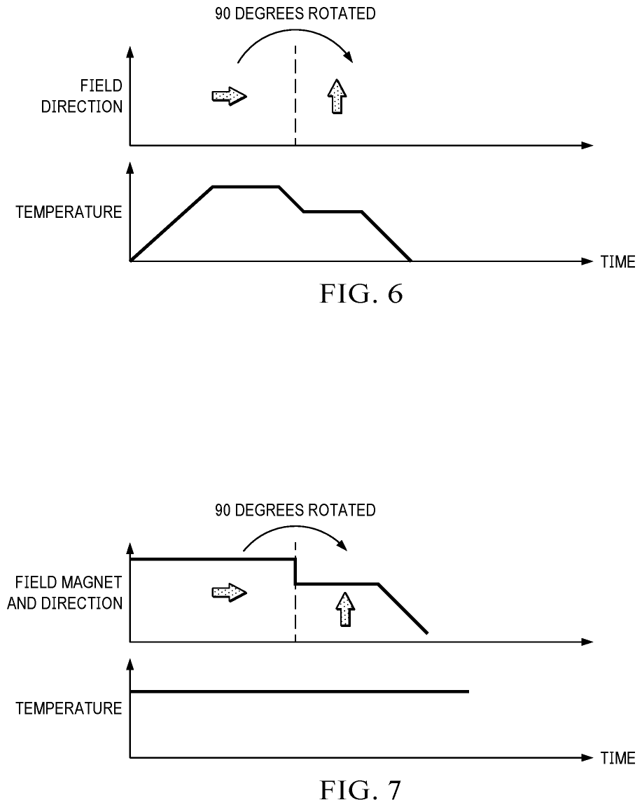

FIG. 6 illustrates field direction and anneal temperature versus time for setting the AF pinning layers in FIG. 2. More particularly, AF pinning layers 201, 207 in FIG. 2 should be set about 90 degrees relative to each other, when two different materials or thicknesses are used for AF pinning layers 201, 207, such that the anneal temperature required to set each AF pinning layer is different, according to an embodiment. In an embodiment, AF pinning layer 201 is set at temperature Y in a set field direction, and then AF pinning layer 207 is set at a lower temperature Z in a set field direction that is about 90 degrees rotated, as shown in FIG. 6.

FIG. 7 illustrates field magnitude and direction and anneal temperature versus time for setting the AF pinning layers shown in FIG. 2, according to an embodiment. The saturation fields of the magnetic material coupled to AF pinning layer 201 and AF pinning layer 207 can be different such that a two-step field application is done. The initial field application is in direction X (shown by the arrow in FIG. 7) and a lower field then about 90 degrees from direction X (shown by the arrow rotated about 90 degrees from X), such that the magnetization direction of fixed layer 202 stays in the direction X and the magnetization direction of pinned layer 206 rotates X+about 90 degrees, as shown in FIG. 7.

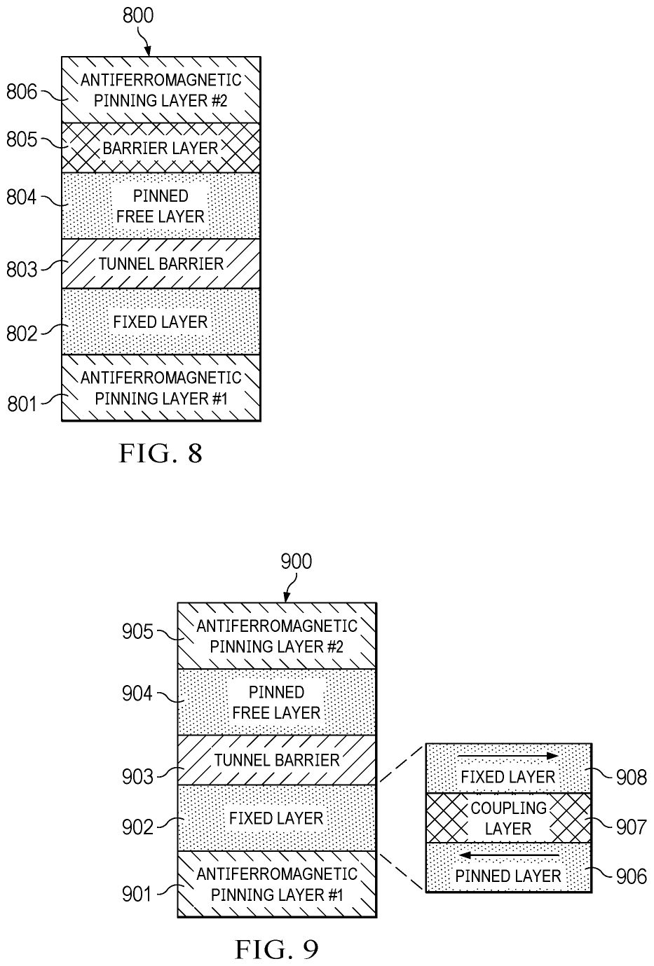

FIG. 8 illustrates a MR sensor stack 800 with a magnetic free layer coupled to an AF pinning material through a barrier layer, according to an embodiment. More particularly, MR sensor stack 800 includes first AF pinning layer 801 (also referred to as AF pinning layer #1), fixed layer 802, tunnel barrier 803, pinned free layer 804, barrier layer 805 and second AF pinning layer 806 (also referred to as AF pinning layer #2). Magnetic free layer 804 is coupled to second AF pinning layer 806 through barrier layer 805. Similar to MR sensor stack 200, the hard axis of pinned free layer 804 will be linear and its magnetization will saturate in the hard axis direction based on the exchange coupling in second AF pinning layer 806. Second AF pinning layer 806 can be comprised of IrMn, PtMn, RhMn, FeMn, or any other suitable AF material. In an embodiment, barrier layer 805 is a thin layer to reduce and control the coupling of pinned free layer 804 to second AF pinning layer 806. In an embodiment, barrier layer 805 has a thickness of less than 1 nm and is composed of tungsten (W), tantalum (Ta), Ru, aluminum (Al), magnesium (Mg) or any other suitable material.

FIG. 9 illustrates an alternative MR sensor stack 900 where a current pulse is passed through the MR sensor stack 900, according to an embodiment. MR sensor stack 900 includes first AF pinning layer 901 (also referred to as AF pinning layer #1), fixed layer 902, tunnel barrier 903, pinned free layer 904 and second AF pinning layer 905 (also referred to as AF pinning layer #2). Pinned free layer 904 is cooled to AF pinning layer 905, which can be comprised of IrMn, PtMn, RhMn, FeMn or any other suitable AF material. In some embodiments, fixed layer 902 (and fixed layers 202 and 802 in FIGS. 2 and 8, respectively) includes pinned layer 906, coupling layer 907 and fixed layer 908. In some embodiments, fixed layer 902 is a synthetic antiferromagnet, pinned layer 906 is in direct contact with first AF layer 901 and coupling layer 907 (e.g., Ru, Rh, Ir, Pt, Pd) couples fixed layer 908 antiferromagnetically to pinned layer 906. This arrangement of layers creates a zero net field since the magnetization directions are anti-aligned.

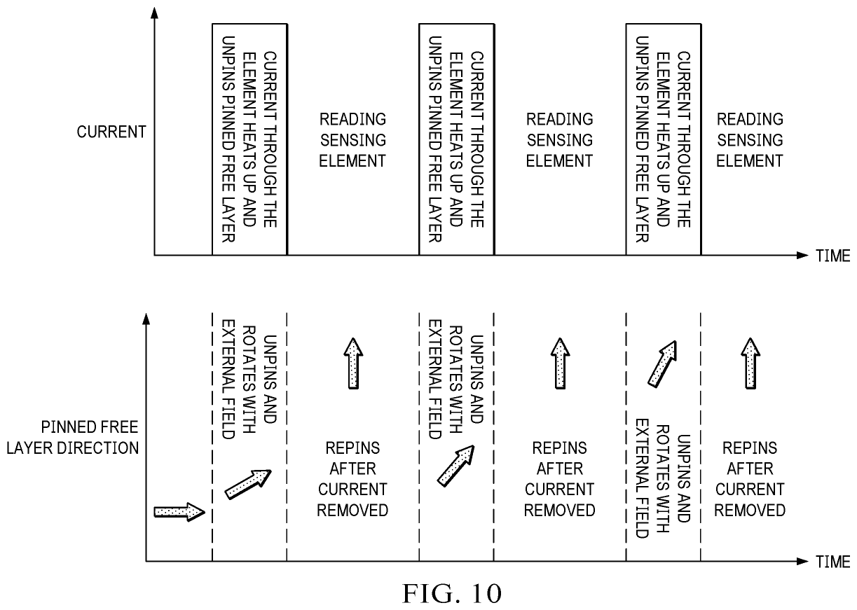

Referring to FIG. 10, in operation, a current pulse is passed through MR sensor stack 900 from first AF pinning layer 901 to second AF pinning layer 905. Self-heating from the current pulse above a blocking temperature of second AF pinning layer 905 unpins the pinned free layer 904 from the second AF pinning layer 905 and allows it to freely rotate in an external field. Removal or reduction of the current pulse below the blocking temperature of the AF pinning layer 905 cools and re-pins the pinned free layer 904 in a new direction of magnetization based on the external field. The MR sensor is then read using, for example, an electric circuit (e.g., a Wheatstone bridge). An advantage of the operation described above is that it provides a stable field during the read and lower noise from the pinned free layer 904 during reading. The procedure for setting of the first and second AF pinning layers 901 and 905 is the same as the procedures described in reference to FIGS. 6 and 7. Note that the current pulsing scheme described above can also be used with sensor stacks 200 and 800 shown in FIGS. 2 and 8, respectively.

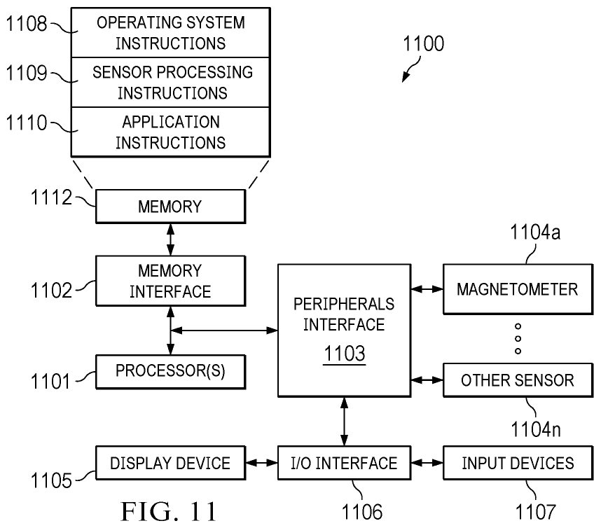

FIG. 11 is a block diagram of an electronic device architecture that includes at least one magnetometer as described in reference to FIGS. 2-10, according to an embodiment. Architecture 1100 includes processor(s) 1101, memory interface 1102, peripherals interface 1103, sensors 1104a . . . 1104n, display device 1105 (e.g., touch screen, LCD display, LED display), I/O interface 606 and input devices 607 (e.g., touch surface/screen, hardware buttons/switches/wheels, virtual or hardware keyboard, mouse). Memory 1112 can include high-speed random access memory and/or non-volatile memory, such as one or more magnetic disk storage devices, one or more optical storage devices and/or flash memory (e.g., NAND, NOR).

Memory 1112 stores operating system instructions 1108, sensor processing instructions 1109 and application instructions 1110. Operating system instructions 1108 include instructions for implementing an operating system on the device, such as iOS, Darwin, RTXC, LINUX, UNIX, WINDOWS, or an embedded operating system such as VxWorks. Operating system instructions 1108 may include instructions for handling basic system services and for performing hardware dependent tasks. Sensor-processing instructions 1109 perform post-processing on sensor data (e.g., averaging, scaling, formatting, calibrating) and provide control signals to sensors. Application instructions 1110 implement software programs that use data from one or more sensors 1104a . . . 1104n, such as navigation, digital pedometer, tracking or map applications, or any other application that needs heading or orientation data. At least one sensor 1104a is a 3-axis magnetometer as described in reference to FIGS. 2-10.

For example, in a digital compass application executed on a smartphone, the raw magnetometer output data is provided to processor(s) 1101 through peripheral interface 1103. Processor(s) 1101 execute sensor-processing instructions 1109, to perform further processing (e.g., averaging, formatting, scaling) of the raw magnetometer output data. Processor(s) 1101 execute instructions for various applications running on the smartphone. For example, a digital compass uses the magnetometer data to derive heading information to be used by a compass or navigation application. The more accurate the magnetometer data the more accurate the heading calculation for the electronic device. Other applications are also possible (e.g., navigation applications, gaming applications, calibrating other sensors).

The disclosed embodiments described above each have a sensing layer that includes a pinned synthetic antiferromagnet or synthetic antiferromagnet, an AF pinning layer composed of at least one of IrMn, PtMn, FeMn, RhMn or any other suitable AF material, and a coupling layer composed of at least one of Ru, Ir, Rh or any other suitable material. The two AF pinning layers are set about 90 degrees relative to each other through a two-step temperature anneal or a two-step magnetic field anneal or combination thereof. In some embodiments, the sensing element of the MR sensor includes a magnetic pinned free layer in direct contact with an AF pinning layer. For such embodiments, the composition of the AF pinning material or roughness will determine the exchange strength of the exchange coupling. In other embodiments, a barrier layer comprising of at least one of W, Ta, Ru, Al, Mg or any other suitable material is inserted between the pinned free layer and the AF pinning layer.

The disclosed embodiments described above also include a method of unpinning a pinned free layer using a current pulse through the MR sensor to self-heat the MR sensor above a blocking temperature of the AF pinning layer, and then reading the MR sensor after the current pulse is reduced or removed and the MR sensor cools back below the blocking temperature. In some embodiments, the MR sensor stacks, 200, 800 shown in FIG. 2 and FIG. 8 could be flipped structurally around the tunnel barrier, so that the second AF pinning layer #2 is below the tunnel barrier and the first AF pinning layer #1 is above the tunnel barrier.

While this specification contains many specific implementation details, these should not be construed as limitations on the scope of any inventions or of what may be claimed, but rather as descriptions of features specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results.

What is claimed is:

1. A magnetoresistance (MR) sensor comprising:
a first antiferromagnetic (AF) pinning layer;
a magnetic fixed layer disposed on the first AF layer;
a tunnel barrier disposed on the magnetic fixed layer;
a magnetic coupled free layer disposed on the tunnel barrier;
a AF coupling layer disposed on the magnetic coupled free layer;
a magnetic pinned layer disposed on the AF coupling layer; and
a second AF pinning layer disposed on the magnetic pinned layer.

2. The MR sensor of claim 1, wherein a hard magnetization axis of the magnetic coupled free layer is about 90 degrees to a pinning direction of the magnetic pinned layer.

3. The MR sensor of claim 1, wherein a saturation field of the coupled free layer in a hard axis direction is defined by a coupling to the pinned layer through the AF coupling layer.

4. The MR sensor of claim 3, wherein a thickness of the AF coupling layer controls a saturation field of the coupled free layer in a hard axis direction.

5. The MR sensor of claim 1, wherein the AF coupling layer provides a bias direction based on a magnetization direction of the pinned layer to align the magnetic coupled free layer in a consistent remanent direction.

6. The MR sensor of claim 1, wherein the first AF pinning layer and the second AF pinning layer comprise different AF materials.

7. The MR sensor of claim 1, wherein the first AF pinning layer and the second AF pinning layer comprise different thicknesses.

8. The MR sensor of claim 1, wherein the second AF pinning layer is below the tunnel barrier and the first AF pinning layer is above the tunnel barrier.

9. The MR sensor of claim 1, wherein the first or second AF pinning layers are composed of at least one of one of platinum manganese (PtMn), iridium manganese (IrMn), rhodium manganese (RhMn) or iron manganese (FeMn).

10. A magnetoresistance (MR) sensor comprising:
a first antiferromagnetic (AF) pinning layer;
a magnetic fixed layer disposed on the first AF layer;
a tunnel barrier disposed on the magnetic fixed layer;
a magnetic pinned free layer disposed on the tunnel barrier; and
a second AF pinning layer disposed on the pinned free layer.

11. The MR sensor of claim 10, wherein a hard axis curve of the pinned free layer is linear and has a direction of magnetization that saturates in the hard axis direction based on an exchange coupling in the second AF pinning layer.

12. The MR sensor of claim 11, wherein an exchange strength of the exchange coupling is determined by a thickness of the second AF pinning layer.

13. The MR sensor of claim 10, further comprising a barrier layer disposed on the magnetic pinned free layer.

14. The MR sensor of claim 13, wherein the barrier layer reduces and controls the coupling of the pinned free layer to the second AF pinning layer.

15. The MR sensor of claim 14, wherein a thickness of the barrier layer is less than 1 nanometer.

16. The MR sensor of claim 10, wherein the second AF pinning layer is below the tunnel barrier and the first AF pinning layer is above the tunnel barrier.

17. The MR sensor of claim 10, wherein the barrier layer is composed of at least one of tungsten (W), tantalum (Ta), Ru, aluminum (Al) or magnesium (Mg).

18. A method of reading from a magnetoresistance (MR) sensor, comprising:
passing an electrical current through the MR sensor, the MR sensor comprising a first antiferromagnetic (AF) pinning layer, a magnetic fixed layer disposed on the first AF layer, a tunnel barrier disposed on the magnetic fixed layer, a magnetic pinned free layer disposed on the tunnel barrier, and a second AF pinning layer disposed on the magnetic pinned layer, the current causing self-heating of the MR sensor that unpins the pinned free layer from the second AF pinning layer and allows it to freely rotate in an external field;
removing the electrical current from the MR sensor, the removal of electrical current causing the pinned free layer to cool and re-pin a new direction based on the external field; and
reading from the MR sensor.

19. The method of claim 18, wherein the first and second AF pinning layers comprise different AF materials, and the method further comprises:
setting the first AF pinning layer at a first anneal temperature in a first field direction; and
setting the second AF pinning layer at a second anneal temperature in a second field direction that is different than the first field direction, where the second anneal temperature is lower than the first anneal temperature.

20. The method of claim 19, wherein saturation fields of magnetic material coupled to the first and second AF pinning layers are different, and the method further comprises:
applying a first field having a first field strength to the MR sensor in a first direction of magnetization; and
applying a second field having a second field strength that is lower than the first field strength to the MR sensor in a second direction of magnetization that is about 90 degrees from the first direction of magnetization, such that a magnetization direction of the fixed layer stays in the first direction of magnetization and the pinned layer rotates into the first direction of magnetization plus about 90 degrees.

21. An electronic device, comprising:
a magnetometer comprising:
a first antiferromagnetic (AF) pinning layer;
a magnetic fixed layer disposed on the first AF layer;
a tunnel barrier disposed on the magnetic fixed layer;
a magnetic coupled free layer disposed on the tunnel barrier;
a AF coupling layer disposed on the magnetic coupled free layer;
a magnetic pinned layer disposed on the AF coupling layer;
a second AF pinning layer disposed on the magnetic pinned layer; and
memory storing instructions that when executed by the one or more processors, cause the one or more processors to perform operations comprising:
obtaining, by the one or more processors from the magnetometer, magnetometer output data; and
determining, by the one or more processors, a directional heading or orientation of the electronic device using the magnetometer output data.

22. An electronic device, comprising:
a magnetometer comprising:
a first antiferromagnetic (AF) pinning layer;
a magnetic fixed layer disposed on the first AF layer;
a tunnel barrier disposed on the magnetic fixed layer;
a magnetic pinned free layer disposed on the tunnel barrier;
a second AF pinning layer disposed on the pinned free layer; and
memory storing instructions that when executed by the one or more processors, cause the one or more processors to perform operations comprising:
obtaining, by the one or more processors from the magnetometer, magnetometer output data; and
determining, by the one or more processors, a directional heading or orientation of the electronic device using the magnetometer output data.
